(19) United States
(12) Patent Application Publication
(10) Pub. No.: US 2026/0363004 A1
(43) Pub. Date: Nov. 12, 2026

(54) SEMICONDUCTOR PACKAGE AND FABRICATION METHOD THEREOF

(71) Applicant: Taiwan Semiconductor Manufacturing Company, Ltd., Hsinchu (TW)

(72) Inventors: Chen-Shien CHEN, Hsinchu County (TW); Tuan-Yu Hung, Changhua County (TW); Yinlung Lu, Hsinchu (TW); Yao-Chun Chuang, Hsinchu City (TW); Tien-Chung Yang, Hsinchu City (TW); Hsu-Hsien Chen, Hsinchu City (TW)

(73) Assignee: Taiwan Semiconductor Manufacturing Company, Ltd., Hsinchu (TW)

(21) Appl. No.: 19/203,176

(22) Filed: May 9, 2025

(51) Int. Cl. H10P 54/00; H10W 20/20; H10W 20/42; H10W 72/00; H10W 74/01; H10W 74/10; H10W 90/00

(52) U.S. Cl. CPC H10P 54/00; H10W 20/20; H10W 20/42; H10W 74/014; H10W 74/111; H10W 72/0198; H10W 90/792

(57) ABSTRACT

A system of integrated circuit (SoIC) structure including a first semiconductor die, a second semiconductor die and a dielectric material is provided. The second semiconductor die is disposed over and electrically connected to the first semiconductor die. The dielectric material is disposed on the first semiconductor die and laterally encapsulating the second semiconductor die, wherein a first maximum width of the first semiconductor die is greater than a second maximum width of the dielectric material.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor wafer. The individual dies are singulated by sawing the integrated circuits along a scribe line. The individual dies are then packaged separately, in multi-chip modules, or in other types of packaging, for example.

The semiconductor industry continues to improve the integration density as well as reliability of various electronic components (e.g., transistors, diodes, resistors, capacitors, etc.) by continual reductions in minimum feature size, which allow more components to be integrated into a given area. These smaller electronic components such as integrated circuit dies may also require smaller packages that utilize less area than packages of the past, in some applications.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A through FIG. 1I are cross-sectional views schematically illustrating a process flow for fabricating System on Integrated Circuit (SoIC) structures in accordance with some embodiments of the present disclosure.

FIG. 2 is a cross-sectional view schematically illustrating the SoIC structure in accordance with some other embodiments of the present disclosure.

FIG. 3 is a cross-sectional view schematically illustrating the SoIC structure in accordance with some alternative embodiments of the present disclosure.

FIG. 4A through FIG. 4M are cross-sectional views schematically illustrating a process flow for fabricating integrated fan-out (InFO) package structures of SoIC structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Packages and the methods of forming the same are provided in accordance with various exemplary embodiments. The intermediate stages of forming the packages are illustrated. The variations of the embodiments are discussed. Throughout the various views and illustrative embodiments, like reference numbers are used to designate like elements.

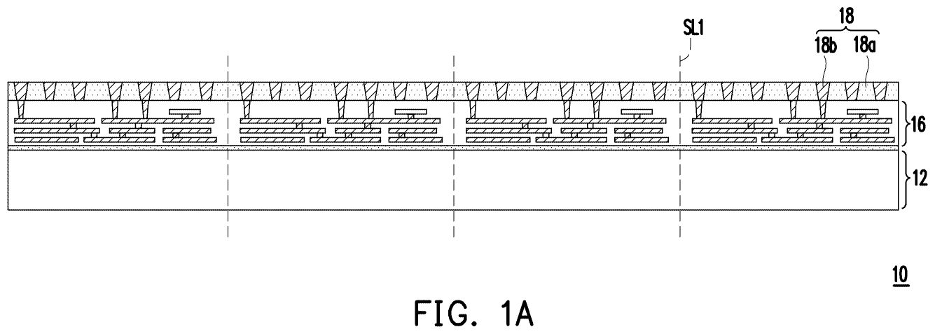

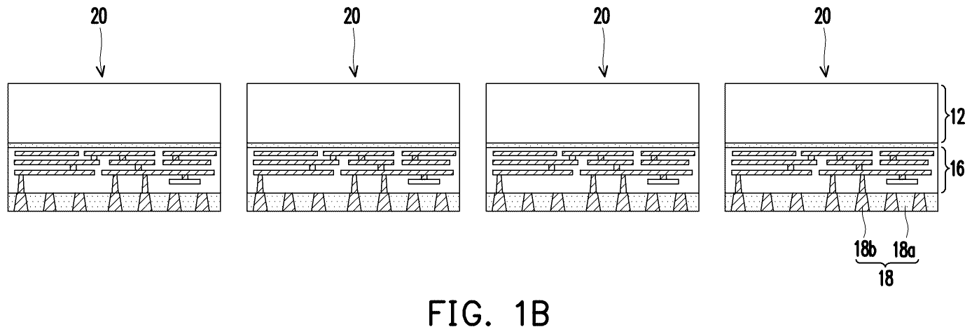

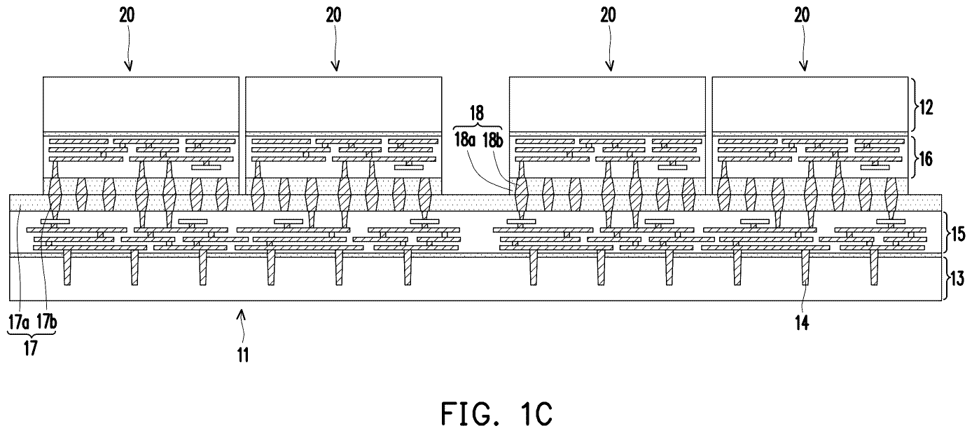

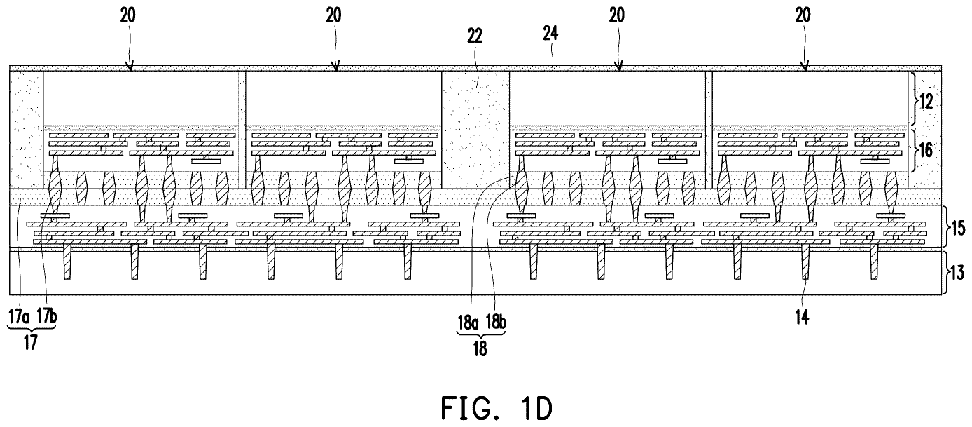

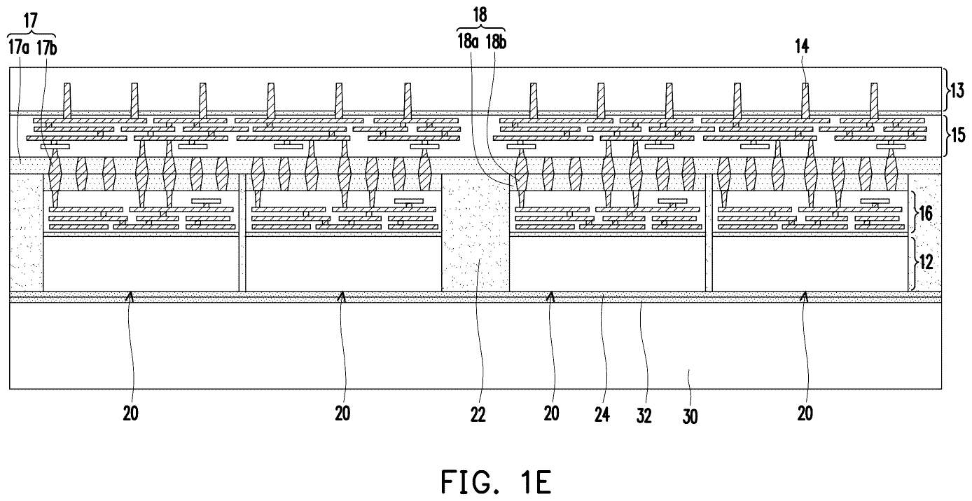

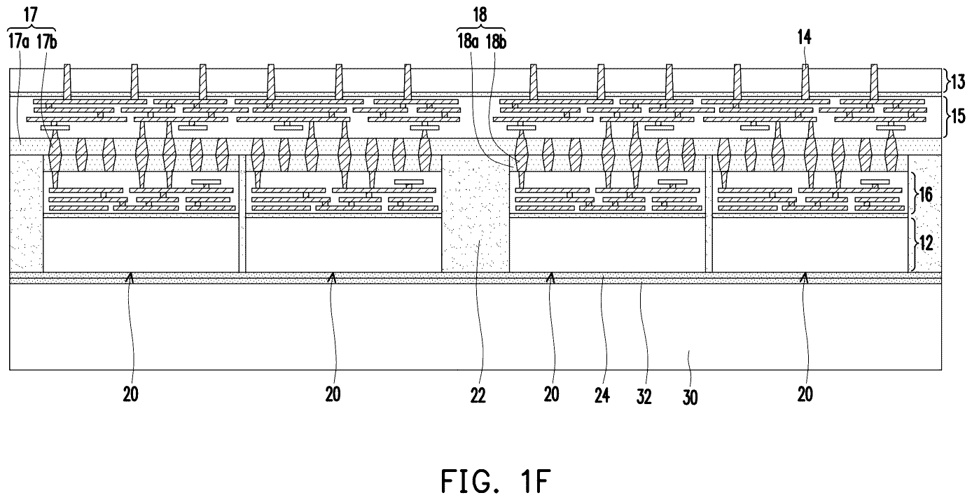

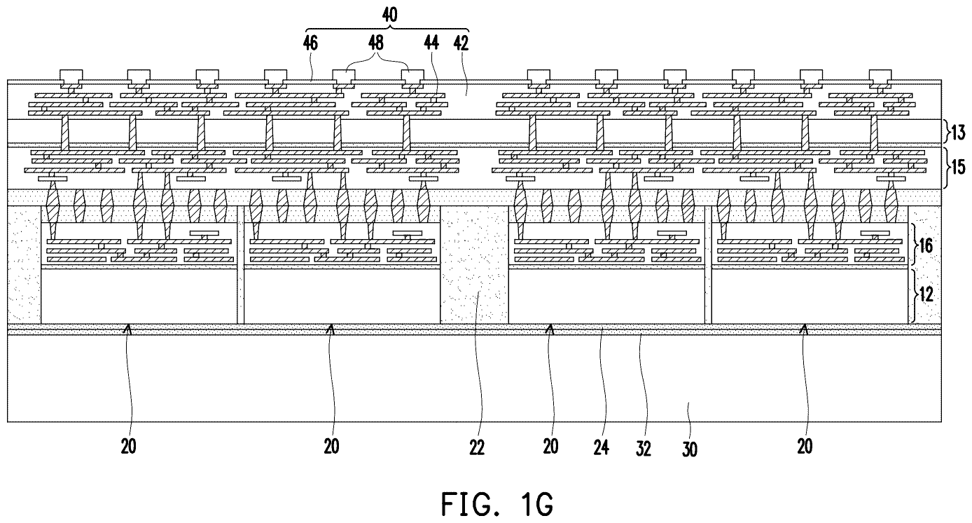

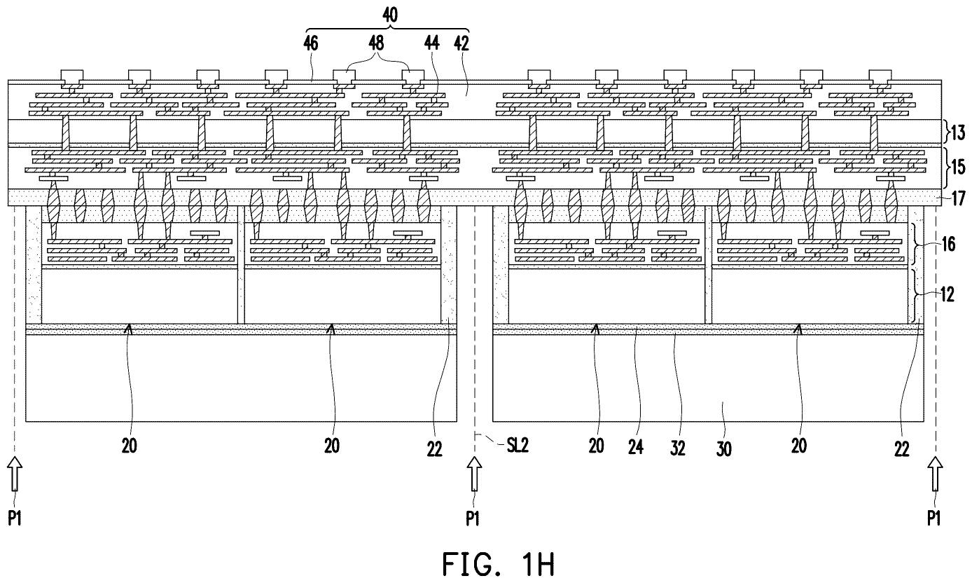

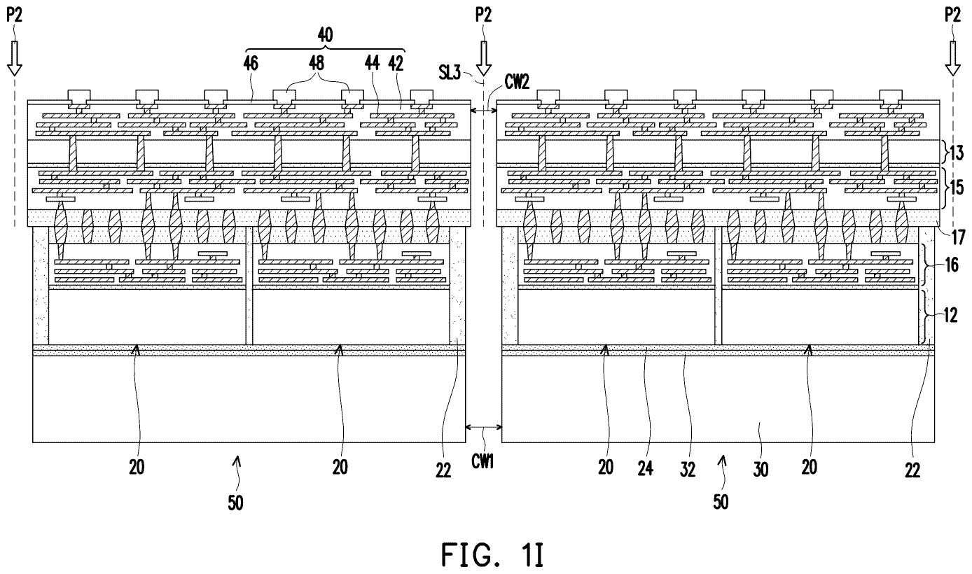

FIG. 1A through FIG. 1I are cross-sectional views schematically illustrating a process flow for fabricating SoIC structures in accordance with some embodiments of the present disclosure.

Referring to FIG. 1A, a semiconductor wafer 10 including semiconductor dies is provided. The semiconductor dies may be logic dies, System-on-Chip (SoC) dies or other suitable semiconductor dies. The semiconductor wafer 10 may include a substrate 12 (e.g., a semiconductor substrate), an interconnect structure 16 disposed on the substrate 12, and a bonding structure 18 disposed on and electrically connected to the interconnect structure 16. The substrate 12 of the semiconductor wafer 10 may include a crystalline silicon substrate. The substrate 12 may include various doped regions depending on design requirements (e.g., p-type substrate or n-type substrate). In some embodiments, the doped regions may be doped with p-type or n-type dopants. The doped regions may be doped with p-type dopants, such as boron or BF₂; n-type dopants, such as phosphorus or arsenic; and/or combinations thereof. The doped regions may be configured for n-type Fin-type Field Effect Transistors (FinFETs) and/or p-type FinFETs. In some alternative embodiments, the substrate 12 may be made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide.

The interconnect structure 16 may include one or more dielectric layers (for example, one or more interlayered dielectric (ILD) layers, intermetal dielectric (IMD) layers, or the like) and interconnect wirings embedded in the one or more dielectric layers, and the interconnect wirings are electrically connected to the semiconductor devices (e.g., FinFETs) formed in the substrate 12. The material of the one or more dielectric layers may include silicon oxide (SiOₓ, where x>0), silicon nitride (SiNₓ, where x>0), silicon oxynitride (SiOₓN_{y}, where x>0 and y>0) or other suitable dielectric material. The interconnect wirings may include metallic wirings. For example, the interconnect wirings include copper wirings, copper pads, aluminum pads or combinations thereof.

The bonding structure 18 may include a bonding dielectric layer 18a and bonding conductors 18b embedded in the bonding dielectric layer 18a. The material of the bonding dielectric layer 18a may be silicon oxide (SiOₓ, where x>0), silicon nitride (SiNₓ, where x>0), silicon oxynitride (SiOₓN_{y}, where x>0 and y>0) or other suitable dielectric material, and the bonding conductors 18b may be conductive vias (e.g., copper vias), conductive pads (e.g., copper pads) or combinations thereof. The bonding structure 18 may be formed by depositing a dielectric material through a chemical vapor deposition (CVD) process (e.g., a plasma enhanced CVD process or other suitable process); patterning the dielectric material to form the bonding dielectric layer 18a including openings or through holes; and filling conductive material in the openings or through holes defined in the bonding dielectric layer 18a to form the bonding conductors 18b embedded in the bonding dielectric layer 18a.

Referring to FIG. 1A and FIG. 1B, the semiconductor wafer 10 is singulated by a wafer sawing process performed along intersected scribe lines SL1 such that multiple singulated semiconductor dies 20 are obtained. Each of the singulated semiconductor dies 20 may include a substrate 12, an interconnect structure 16 disposed on the substrate 12, and a bonding structure 18 disposed on the interconnect structure 16.

Referring to FIG. 1C, a semiconductor wafer 11 including semiconductor dies arranged in array is provided, and the singulated semiconductor dies 20 singulated from the semiconductor wafer 20 (shown in FIG. 1A) are picked and placed on as well as bonded to the semiconductor wafer 11. The singulated semiconductor dies 20 placed on the semiconductor wafer 11 may be classified into multiple groups of semiconductor dies 20. After the singulated semiconductor dies 20 are picked and placed on as well as bonded to the semiconductor wafer 11, a chip probing process may be performed to increase yields. The semiconductor dies in the semiconductor wafer 11 may be logic dies, System-on-Chip (SoC) dies or other suitable semiconductor dies. In some embodiment, the semiconductor dies 20 and the semiconductor dies in the semiconductor wafer 11 perform the same function. In some other embodiments, the semiconductor dies 20 and the semiconductor dies in the semiconductor wafer 11 perform different functions. For example, the semiconductor dies 20 and the semiconductor dies in the semiconductor wafer 11 are System on Chip (SoC) dies. The semiconductor wafer 11 may include a substrate 13 (e.g., a semiconductor substrate), through substrate vias 14 embedded in the substrate 13, an interconnect structure 15 disposed on the substrate 13, and a bonding structure 17 disposed on the interconnect structure 15, wherein the through substrate vias 14 are electrically connected to the interconnect structure 15. The substrate 13 of the semiconductor wafer 11 may include a crystalline silicon wafer. The substrate 13 may include various doped regions depending on design requirements (e.g., p-type substrate or n-type substrate). In some embodiments, the doped regions may be doped with p-type or n-type dopants. The doped regions may be doped with p-type dopants, such as boron or BF₂; n-type dopants, such as phosphorus or arsenic; and/or combinations thereof. The doped regions may be configured for n-type Fin-type Field Effect Transistors (FinFETs) and/or p-type FinFETs. In some alternative embodiments, the substrate 13 may be made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide.

The through substrate vias 14 may be formed by forming recesses in the substrate 13 by, for example, etching, milling, laser techniques, a combination thereof, and/or the like. A thin barrier layer may be conformally deposited over the front side of the substrate 13 and in the openings, such as by chemical vapor deposition (CVD), atomic layer deposition (ALD), physical vapor deposition (PVD), thermal oxidation, a combination thereof, and/or the like. The barrier layer may comprise a nitride or an oxynitride, such as titanium nitride, titanium oxynitride, tantalum nitride, tantalum oxynitride, tungsten nitride, a combination thereof, and/or the like. A conductive material is deposited over the thin barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer may be removed from the front side of the substrate 13 by, for example, chemical mechanical polishing (CMP). Thus, in some embodiments, the through substrate vias 14 may include a conductive material and a thin barrier layer between the conductive material and the substrate 13. In some embodiments, the through substrate vias 14 may extend through one or more layers of the interconnect structure 15 and protrude into the substrate 13. As illustrated in FIG. 1C, the through substrate vias 14 are buried in the substrate 13 and the interconnect structure 15. The through semiconductor vias 14 are not revealed from a back surface of the substrate 13 at this stage.

The interconnect structure 15 may include one or more dielectric layers (for example, one or more interlayer dielectric (ILD) layers, intermetal dielectric (IMD) layers, or the like) and interconnect wirings embedded in the one or more dielectric layers, and the interconnect wirings are electrically connected to the semiconductor devices (e.g., FinFETs) formed in the substrate 13. The material of the one or more dielectric layers may include silicon oxide (SiOₓ, where x>0), silicon nitride (SiNₓ, where x>0), silicon oxynitride (SiOₓN_{y}, where x>0 and y>0) or other suitable dielectric material. The interconnect wirings may include metallic wirings. For example, the interconnect wirings include copper wirings, copper pads, aluminum pads or combinations thereof.

The bonding structure 17 may include a bonding dielectric layer 17a and bonding conductors 17b embedded in the bonding dielectric layer 17a. The material of the bonding dielectric layer 17a may be silicon oxide (SiOₓ, where x>0), silicon nitride (SiNₓ, where x>0), silicon oxynitride (SiOₓN_{y}, where x>0 and y>0) or other suitable dielectric material, and the bonding conductors 17b may be conductive vias (e.g., copper vias), conductive pads (e.g., copper pads) or combinations thereof. The bonding structure 17 may be formed by depositing a dielectric material through a chemical vapor deposition (CVD) process (e.g., a plasma enhanced CVD process or other suitable process); patterning the dielectric material to form the bonding dielectric layer 17a including openings or through holes; and filling conductive material in the openings or through holes defined in the bonding dielectric layer 17a to form the bonding conductors 17b embedded in the bonding dielectric layer 17a.

A chip-to-wafer bonding process is performed to bond the bonding structures 18 of the singulated semiconductor dies 20 with the bonding structure 17 of the semiconductor wafer 11. The chip-to-wafer bonding process may be a bonding process that includes dielectric-to-dielectric bonding and metal-to-metal bonding. After performing the above-mentioned chip-to-wafer bonding process, a dielectric-to-dielectric bonding interface is formed between the bonding dielectric layer 18a and the bonding dielectric layer 17a, and metal-to-metal bonding interfaces are formed between the bonding conductors 18c and bonding conductors 17b.

Referring to FIG. 1D, a dielectric layer (e.g., a gap filling layer) 22 is formed on the semiconductor wafer 11 and laterally encapsulates the semiconductor dies 20. In some embodiments, a material of the dielectric material 22 includes silicon oxide. The dielectric material 22 is in contact with the sidewalls of the semiconductor dies 20 as well as the top surface of the bonding structure 17 (i.e. the top surface of the bonding dielectric layer 17a) uncovered by the semiconductor dies 20. The thickness of the dielectric material 22 substantially equals to the thickness of the semiconductor dies 20. In other words, the back surfaces of the semiconductor dies 20 may substantially level with the top surface of the dielectric material 22 is formed. For example, a gap filling material is formed on the semiconductor wafer 11 to cover the semiconductor dies 20. The gap filling material may be a dielectric material (e.g., TEOS formed oxide or other suitable dielectric material) formed through a gap filling process or the like. The gap filling material fills gaps between neighboring semiconductor dies 20 and laterally encapsulates the semiconductor dies 20. As illustrated in FIG. 1D, the gap filling material is in contact with sidewalls of the semiconductor dies 20 and the bonding structure 17 of the semiconductor wafer 11. Then, a removal process may be performed to form the dielectric material 22. The removal process partially removes the gap filling material such that the gap filling material can be thinned down to reveal the back surfaces of the semiconductor dies 20. The removal process may be a mechanical grinding process, a chemical mechanical polishing (CMP) process, combinations thereof, or other suitable thinning process.

After the dielectric material 22 is formed, a bonding layer 24 is formed on the back surfaces of the semiconductor dies and the top surface of the dielectric material 22. The material of the bonding layer 24 may be silicon oxide (SiOₓ, where x>0), silicon nitride (SiNₓ, where x>0), silicon oxynitride (SiOₓN_{y}, where x>0 and y>0) or other suitable dielectric material.

Referring to FIG. 1D and FIG. 1E, a support substrate 30 is provided. In some embodiments, the support substrate 30 is a silicon substrate, a glass substrate, a ceramic carrier, or the like. The support substrate 30 may have a round top-view shape and a size of a silicon wafer. For example, the support substrate 30 may have an 8-inch diameter, a 12-inch diameter, or the like. The support substrate 30 may have a bonding layer 32 formed thereon. The material of the bonding layer 32 may be silicon oxide (SiOₓ, where x>0), silicon nitride (SiNₓ, where x>0), silicon oxynitride (SiOₓN_{y}, where x>0 and y>0) or other suitable dielectric material. The top surface of the bonding layer 32 is substantially planar. The resulted structure (i.e., a reconstructed wafer structure) illustrated in FIG. 1D is flipped upside down and placed onto the bonding layer 32 carried by the support substrate 30 such that the bonding layer 24 faces and is in contact with the bonding layer 32 carried by the support substrate 30. A wafer-to-wafer bonding process is performed to bond the bonding layer 24 and the bonding layer 32 carried by the support substrate 30. For example, the bonding layer 32 and the bonding layer 24 are bonded to each other through a fusion bonding process or a direct wafer bonding process. In some embodiments, the bonding layer 32 and the bonding layer 24 are substantial identical in material. In some other embodiments, the bonding layer 32 and the bonding layer 24 are different in material.

Referring to FIG. 1D through FIG. 1F, after the resulted structure illustrated in FIG. 1D is flipped upside down and transfer bonded onto the support substrate 30, a removal process is performed to partially remove the substrate 13 until the through semiconductor vias 14 are revealed from the back surface of the substrate 13 of the semiconductor wafer 11. The through semiconductor vias 14 may protrude from the back surface of the substrate 13 of the semiconductor wafer 11 at this stage. In some embodiments, the above-mentioned removal process of the substrate 13 includes a chemical mechanical polishing (CMP) process, a mechanical grinding process, combinations thereof or the like.

Referring to FIG. 1G, a backside redistribution structure 40 including stacked dielectric layers 42 and multiple layers of redistribution wirings 44 is formed on the revealed through semiconductor vias 14 and the back surface of the substrate 13 of the semiconductor wafer 11, wherein the redistribution wirings 44 are electrically connected to the through semiconductor vias 14. The stacked dielectric layers 42 of the backside redistribution structure 40 may be formed by a deposition process (e.g., CVD process or the like) of dielectric material followed by a patterning process (e.g., photolithography process and etch process). The material of the stacked dielectric layer 42 may be or include silicon oxide (SiOₓ, where x>0), silicon nitride (SiNₓ, where x>0), silicon oxynitride (SiOₓN_{y}, where x>0 and y>0) or other suitable dielectric material. The redistribution wirings 44 of the backside redistribution structure 40 may be formed by a deposition process (e.g., CVD process or the like) of conductive material followed by a patterning process (e.g., photolithography process and etch process). The material of the redistribution wirings 44 may be or include copper or other suitable conductive material.

As illustrated in FIG. 1G, after forming the stacked dielectric layers 42 and the redistribution wirings 44, a protection layer 46 is formed over the stacked dielectric layers 42 and the redistribution wirings 44. The protection layer 46 is formed to cover the stacked dielectric layers 42 and the redistribution wirings 44, and the protection layer 46 includes openings for revealing the topmost redistribution wirings 44. The material of the protection layer 46 may be or include polyimide or other suitable polymer. Then, the conductive terminals 48 are formed over the protection layer 46 such that the conductive terminals 48 are electrically connected to the through semiconductor vias 14 through the redistribution wirings 44. The conductive terminals 48 land on and are electrically connected to the topmost redistribution wirings 44 through the openings defined in the protection layer 46. In some embodiments, the conductive terminals 48 include controlled collapse chip connection (C4) bumps. The formation of the conductive terminals 48 may include forming under bump metallurgy (UBM) layers (not shown) over the backside redistribution structure 40, forming a patterned mask (not shown) such as a photoresist layer over the UBM layers, and then performing a plating process on the exposed UBM layers. The patterned mask and the portions of the UBM layers covered by the patterned mask are then removed, leaving the conductive terminals 48. A reflow process may be optionally performed to re-shape the profile of the conductive terminals 48. In accordance with some embodiments, the UBM layers include titanium layers and copper layers over the titanium layers. The UBM layers may be formed using, for example, Physical Vapor Deposition (PVD). The plating may be performed using, for example, electroless plating.

Referring to FIG. 1G through FIG. 1I, a singulation process including two cutting processes is performed to obtain multiple singulated SoIC structures 50. The above-mentioned singulation process may include a wafer sawing process P1 (illustrated in FIG. 1H) followed by a laser grooving process P2 (illustrated in FIG. 1I). The wafer sawing process P1 is performed along intersected scribe lines SL2 to cut the support substrate 30, bonding layer 32, the bonding layer 24 and the dielectric material 22 until the bonding structure 17 of the semiconductor wafer 11 is revealed, as illustrated in FIG. 1H. The wafer sawing process P1 may be performed to stop on the revealed surface of the bonding dielectric layer 17a of the bonding structure 17. Due to process variations of the wafer sawing process P1, the cutting depth of the wafer sawing process P1 may varies slightly such that a ring-shaped recess or curved surface (not shown in FIG. 1H) may be formed on the revealed surface of the bonding dielectric layer 17a of the bonding structure 17. The bonding dielectric layer 17a may include a first portion (e.g., a central portion) which is covered by the semiconductor dies 20 and the dielectric material 22. The bonding dielectric layer 17a may further include a second portion (e.g. a ring-shaped periphery portion) surrounding the first portion which is uncovered by the semiconductor dies 20 and the dielectric material 22. The thickness of the first portion of the bonding dielectric layer 17a is greater than the thickness of the second portion of the bonding dielectric layer 17a. For example, the thickness of the bonding dielectric layer 17a of the bonding structure 17 may be about 6 micrometers, and the depth of the above-mentioned recess or curved surface may range from about 0.1 micrometer to about 5 micrometers. In other words, the minimum thickness of the above-mentioned second portion of the bonding dielectric layer 17a may range from about 1 micrometer to about 5.9 micrometers. Furthermore, the ratio of the depth of the above-mentioned recess or curved surface to the thickness of the bonding dielectric layer 17a may range from about 1.6% to about 85%.

After performing the wafer sawing process P1 illustrated in FIG. 1H, the laser grooving process P2 illustrated in FIG. 1I is performed along intersected scribe lines SL3 to cut the semiconductor wafer 11 so as to obtain multiple singulated SoIC structures 50. The laser grooving process P2 utilizes ultraviolet (UV) laser radiation to melt, vaporize and remove the portions of the semiconductor wafer 11 along the intersected scribe lines SL3. Since the wafer sawing process P1 (illustrated in FIG. 1H) is performed prior to the laser grooving process P2 (illustrated in FIG. 1I), the UV laser radiation utilized in the laser grooving process P2 does not penetrate through the dielectric material 22, the bonding layer 24 and the bonding layer 32 as well as does not irradiate onto the support substrate 30 (e.g., the silicon carrier) such that delamination issue between the dielectric material 22 and the support substrate 30 and/or crack issue of the dielectric material 22 resulted from the UV laser radiation can be prevented effectively.

In some embodiments, a cutting width CW1 of the wafer sawing process P1 is greater than a cutting width CW2 of the laser grooving process P2, as illustrated in FIG. 1I. The difference between the cutting width CW1 of the wafer sawing process P1 and the cutting width CW2 of the laser grooving process P2 may be about 4 micrometers. Since the cutting width CW1 of the wafer sawing process P1 is greater than the cutting width CW2 of the laser grooving process P2, as illustrated in FIG. 1I, the UV laser radiation utilized in the laser grooving process P2 does not irradiate onto the support substrate 30. Accordingly, delamination issue between the dielectric material 22 and the support substrate 30 and/or crack issue of the dielectric material 22 resulted from the UV laser radiation can be prevented effectively.

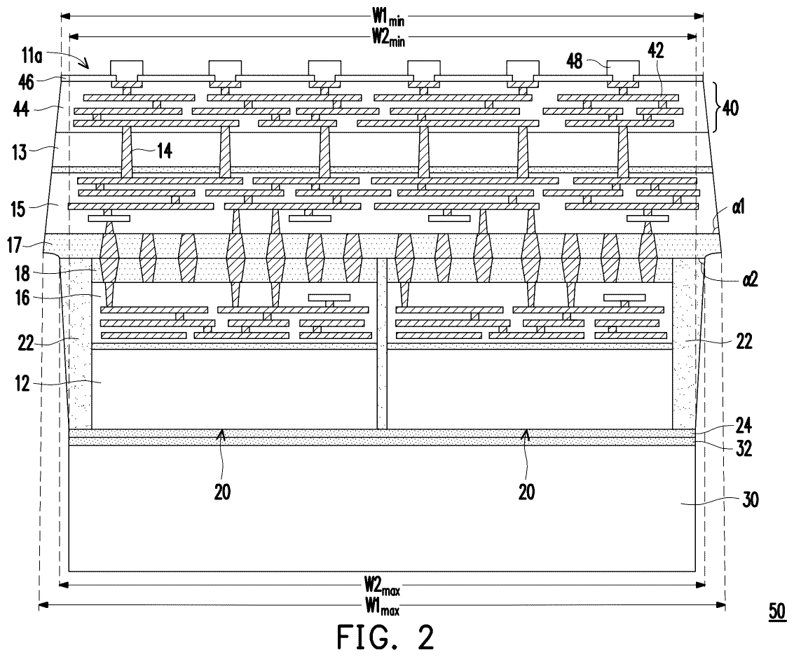

FIG. 2 is a cross-sectional view schematically illustrating the SoIC structure 50 in accordance with some other embodiments of the present disclosure.

Referring to FIG. 2, the SoIC structures 50 may each includes a first semiconductor die 11a, at least one second semiconductor die 20 (e.g., two second semiconductor dies 20) and a dielectric material 22 is provided. The second semiconductor dies 20 are disposed over and electrically connected to the first semiconductor die 11a. The dielectric material 22 is disposed on the first semiconductor die 11a as well as laterally encapsulates the second semiconductor dies 20, wherein the first maximum width W1ₘₐₓ of the first semiconductor die 11a is greater than the second maximum width W2ₘₐₓ of the dielectric material 22. The first minimum width W1ₘᵢₙ of the first semiconductor die 11a may be greater than the second minimum width W2ₘᵢₙ of the dielectric material 22. Furthermore, the first sidewalls of the first semiconductor die 11a are first tapered sidewalls, and the second sidewalls of the dielectric material 22 are second tapered sidewalls.

The difference between the first minimum width W1ₘᵢₙ of the first semiconductor die 11a and the second minimum width W2ₘᵢₙ of the dielectric material 22 may be about 2 micrometers. The above-mentioned difference between the first minimum width W1ₘᵢₙ of the first semiconductor die 11a and the second minimum width W2ₘᵢₙ of the dielectric material 22 is defined as laser-to-saw gap.

As illustrated in FIG. 2, the first semiconductor die 11a includes a first substrate 13, a first interconnect structure 15 disposed on a front surface of the first substrate 13, and a first bonding structure 17 disposed on and electrically connected to the first interconnect structure 15, wherein the first bonding structure 17 is in contact with the second semiconductor dies 20 and the dielectric material 22, and the first bonding structure 17 has the first maximum width W1ₘₐₓ of the first semiconductor die 11a. In some embodiments, the first semiconductor die 11a further includes a backside redistribution structure 40 disposed on a back surface of the first substrate 13, wherein the backside redistribution structure 40 has the first minimum width W1ₘᵢₙ of the first semiconductor die 11a. In some embodiments, the first substrate 13 has a first surface interfacing the first interconnect structure 15, and a first included angle α1 between the first surface of the first substrate 13 and the sidewalls of the first semiconductor die 11a is less than 90 degrees. In some embodiments, the dielectric material 22 has a second surface interfacing the first bonding structure 17 of the first semiconductor die 11a, and a second included angel α2 between the second surface of the dielectric material 22 and the sidewalls of the dielectric material 22 is less than 90 degrees. As illustrated in FIG. 2, the second semiconductor die 20 may each include a second substrate 12, a second interconnect structure 16 disposed on a front surface of the second substrate 12, and a second bonding structure 18 disposed on and electrically connected to the second interconnect structure 16, wherein the second bonding structure 18 is in contact with and electrically connected to the first bonding structure 17.

In some embodiments, the SoIC structure 50 further includes a support substrate 30, wherein the second semiconductor die 20 and the dielectric material 22 are disposed between the first semiconductor die 11a and the support substrate 30. Furthermore, the SoIC structure 50 may further include the bonding layer 32 and the bonding layer 24, wherein both of the bonding layer 32 and the bonding layer 24 are disposed between the support substrate 30 and the second semiconductor die 20 as well as between the support substrate 30 and the dielectric material 22.

In some embodiments, a difference between the first minimum width W1ₘᵢₙ of the first semiconductor die 11a and the second minimum width of the dielectric material 22 is greater than about 2 micrometers. In some embodiments, a difference between the first maximum width W1ₘₐₓ of the first semiconductor die 11a and the second maximum width W2ₘₐₓ of the dielectric material 22 is greater than about 8 micrometers.

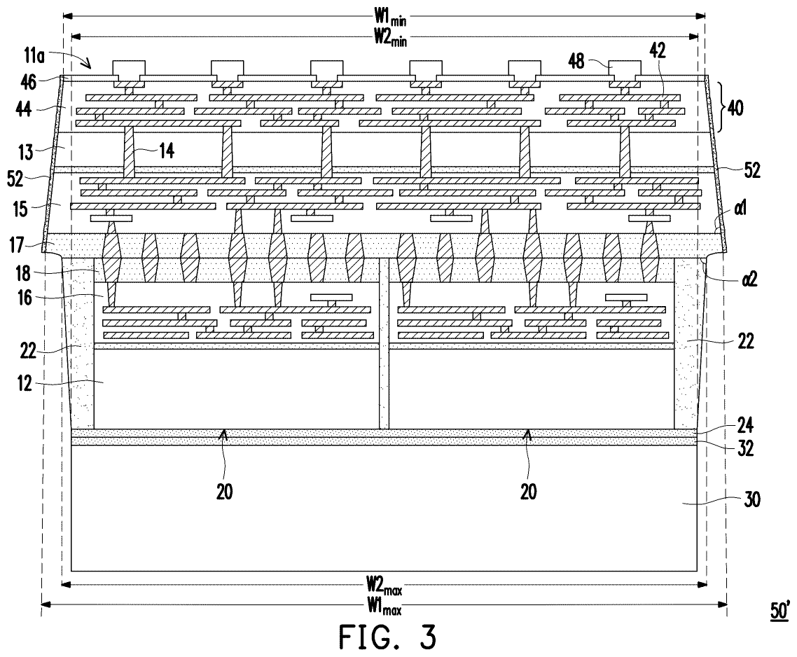

FIG. 3 is a cross-sectional view schematically illustrating the SoIC structure 50′ in accordance with some alternative embodiments of the present disclosure.

Referring to FIG. 2 and FIG. 3, the SoIC structure 50′ illustrated in FIG. 3 is similar with the SoIC structure 50 illustrated in FIG. 2 except that the SoIC structure 50′ further includes a recast layer 52 covering the first tapered sidewalls of the first semiconductor die 11a. As illustrated in FIG. 3, the recast layer 52 does not cover the second tapered sidewalls of the dielectric material 22. Furthermore, the recast layer 52 illustrated in FIG. 3 is spaced from the dielectric material 22.

In the above-mentioned fabrication processes of the SoIC structure 50 or the SoIC structure 50′, since delamination issue between the dielectric material 22 and the support substrate 30 and/or crack issue of the dielectric material 22 resulted from the UV laser radiation can be prevented effectively, fabrication yields (or process window) of the SoIC structure 50 or the SoIC structure 50′ may be enhanced. Furthermore, reliability of the SoIC structure 50 or the SoIC structure 50′ can be improved.

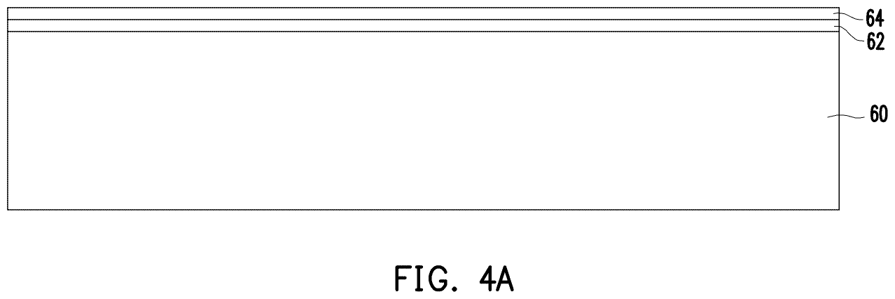

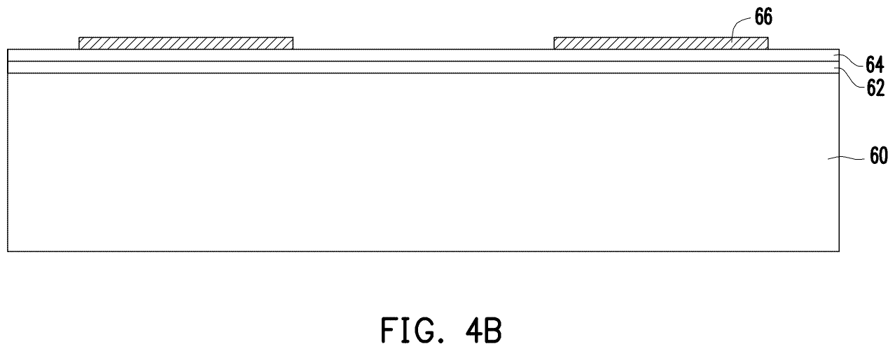

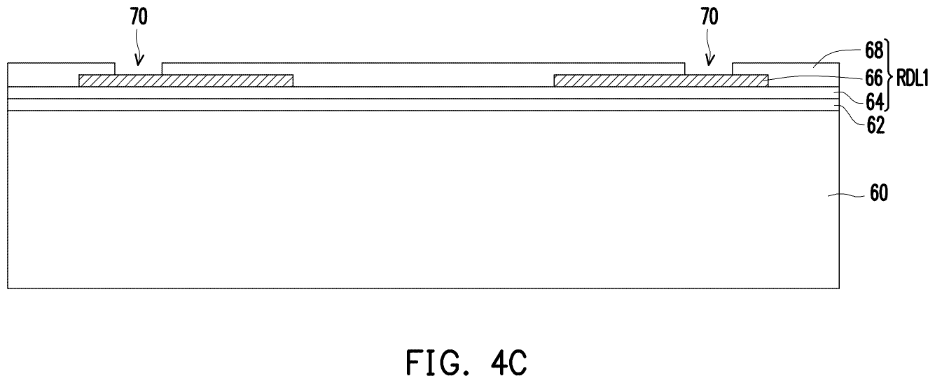

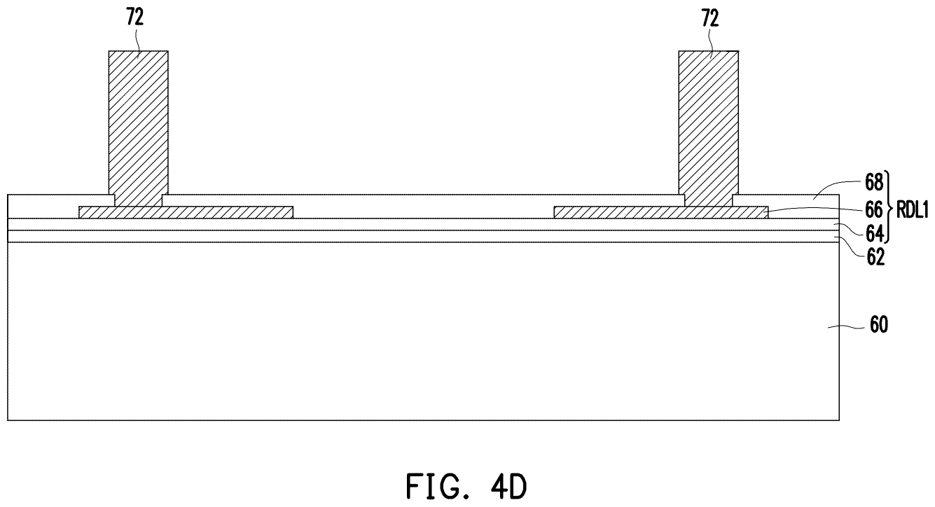

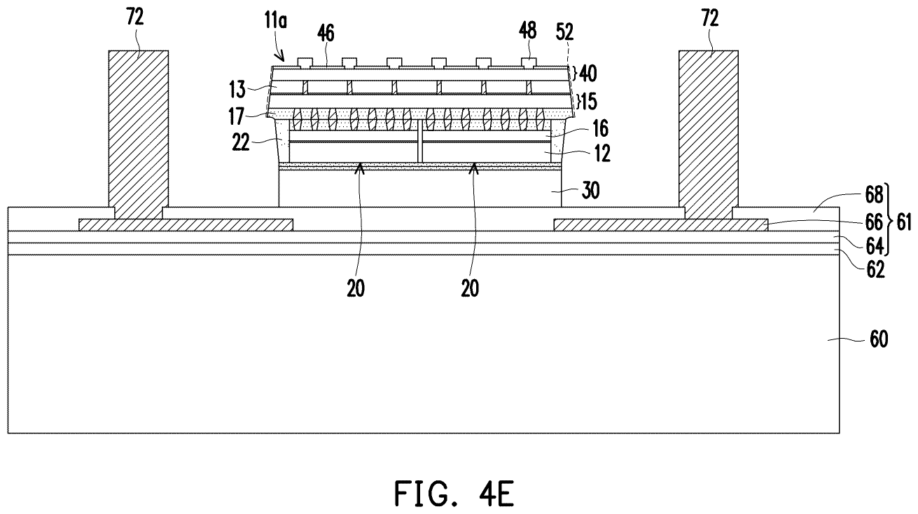

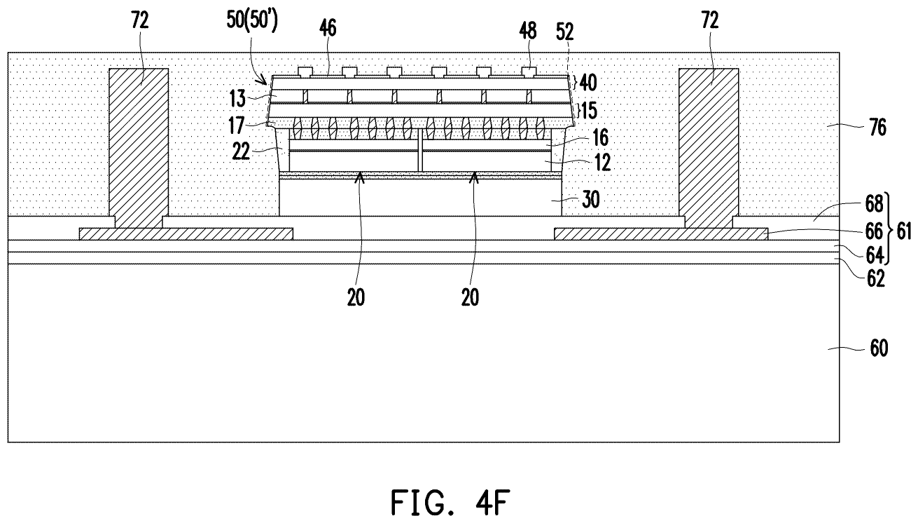

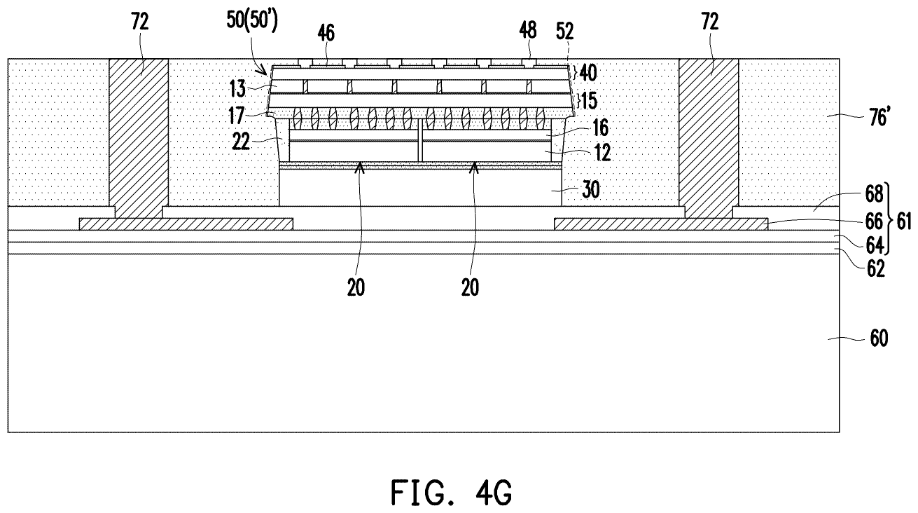

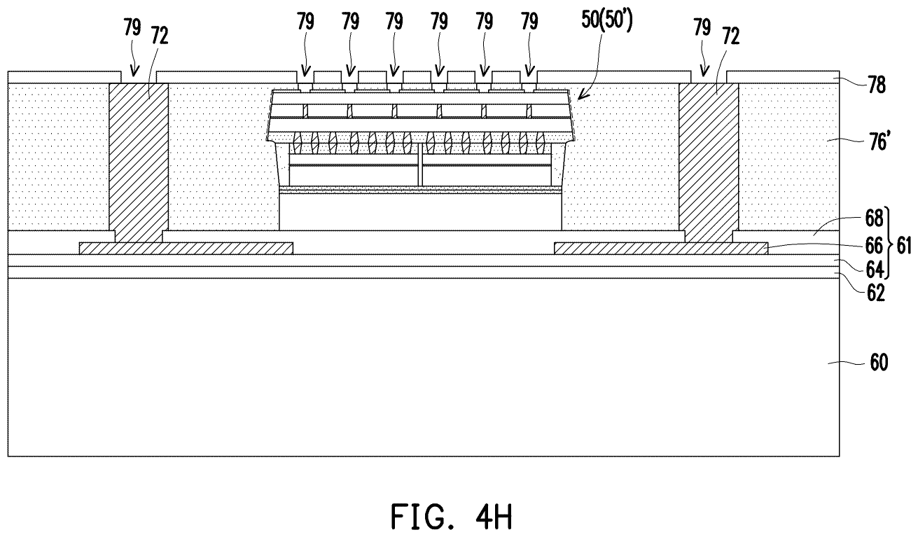

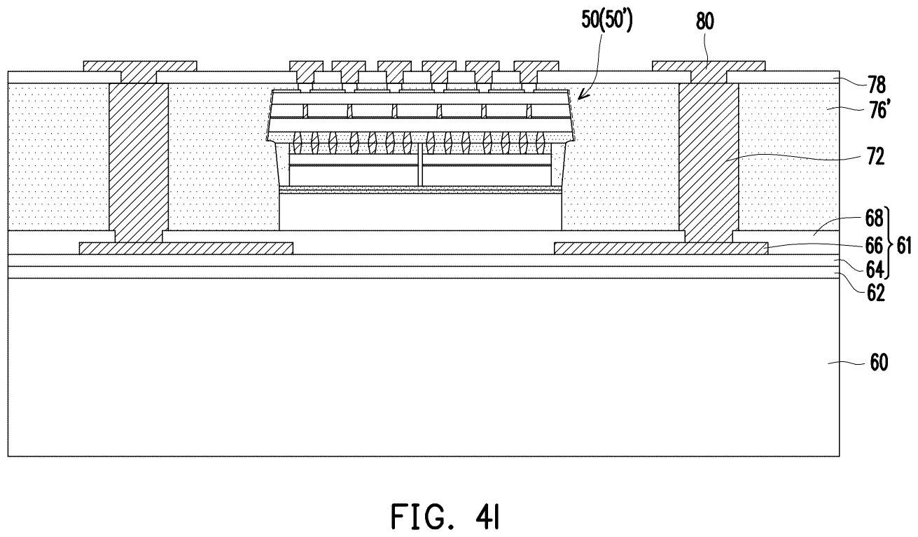

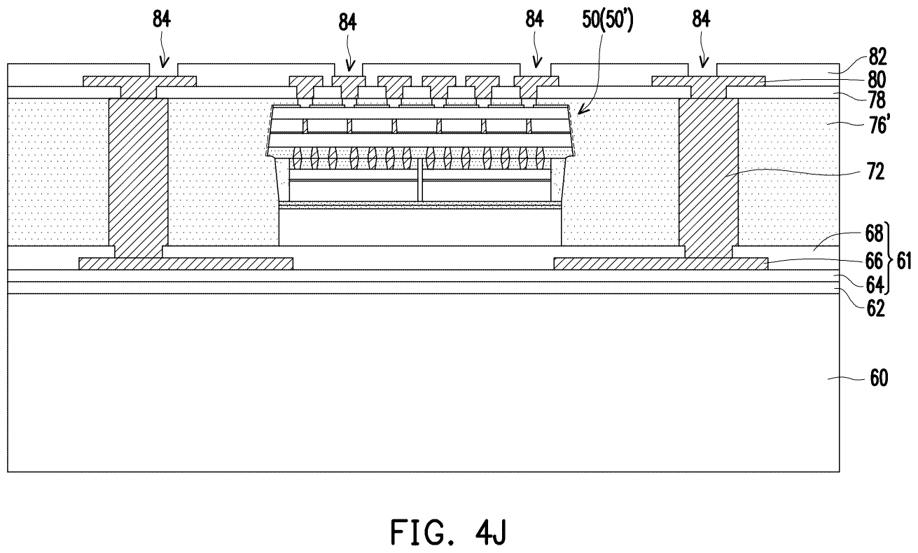

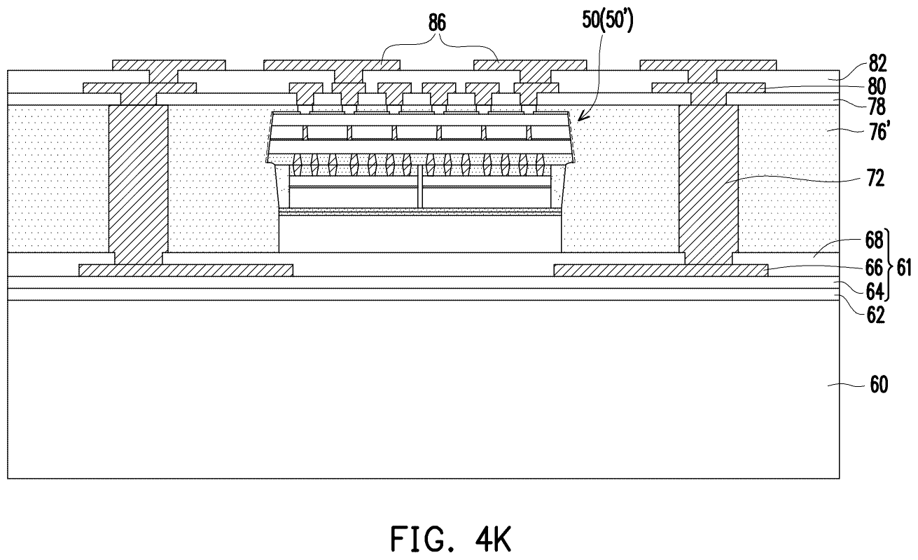

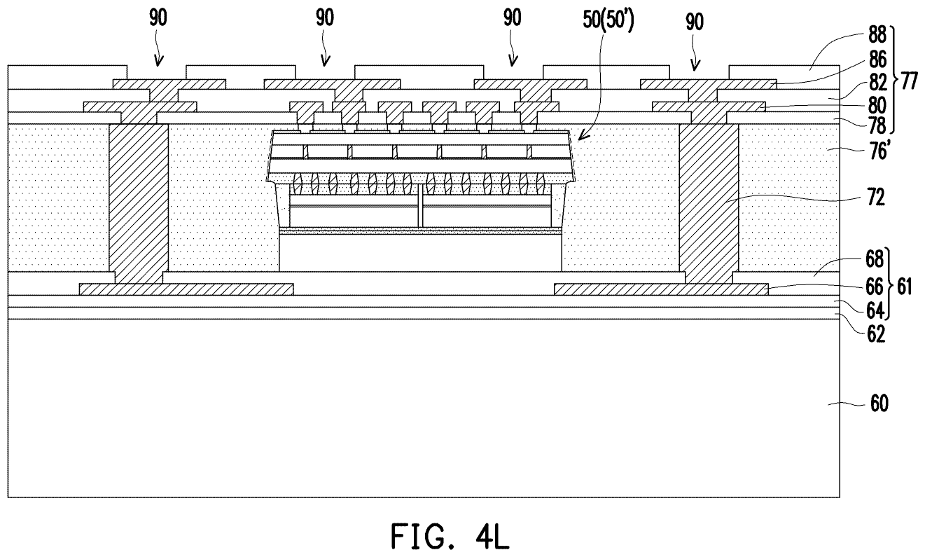

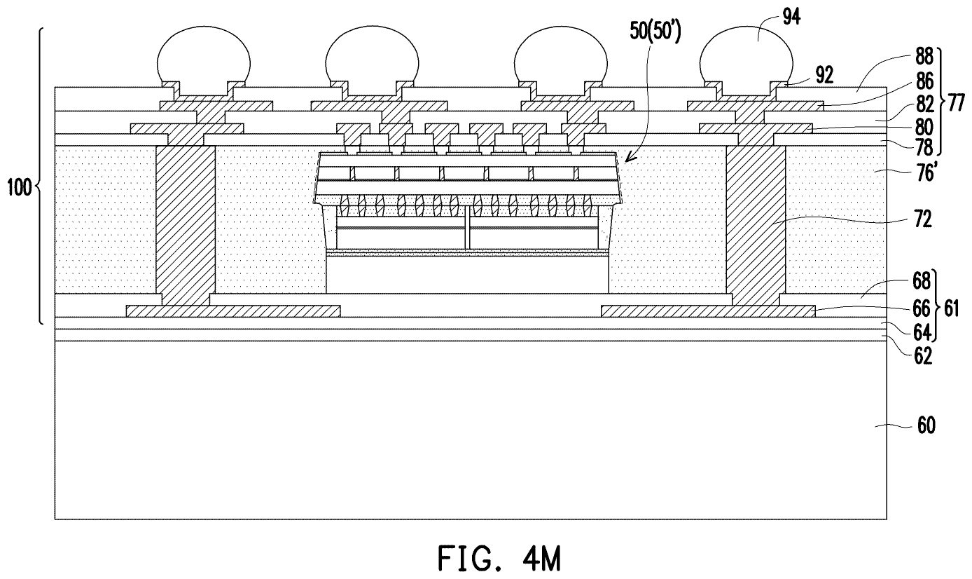

FIG. 4A through FIG. 4M are cross-sectional views schematically illustrating a process flow for fabricating integrated fan-out (InFO) package structures of SoIC structure in accordance with some embodiments of the present disclosure. FIG. 4A through FIG. 4M illustrate the packaging process of the SoIC structure 50 shown in FIG. 2 or the SoIC structure 50′ shown in FIG. 3 to form InFO package structures, so that the overlying electrical connectors (such as solder regions) may be distributed to regions larger than the SoIC structure 50 or the SoIC structure 50′.

Referring to FIG. 4A, a carrier 60 including a de-bonding layer 62 formed thereon is provided. In some embodiments, the carrier 60 is a glass substrate, a ceramic carrier, or the like. The carrier 60 may have a round top-view shape and a size of a silicon wafer. For example, carrier 60 may have an 8-inch diameter, a 12-inch diameter, or the like. The de-bonding layer 62 may be formed of a polymer-based material (e.g., a Light To Heat Conversion (LTHC) material), which may be subsequently removed along with the carrier 60 from the overlying structures that will be formed in subsequent steps. In some embodiments, the de-bonding layer 62 is formed of an epoxy-based thermal-release material. In other embodiments, the de-bonding layer 62 is formed of an ultra-violet (UV) glue. The de-bonding layer 62 may be dispensed as a liquid and cured. In alternative embodiments, the de-bonding layer 62 is a laminate film and is laminated onto the carrier 60. The top surface of the de-bonding layer 62 is substantially planar.

Referring to FIG. 4A through FIG. 4C, a redistribution circuit structure 61 including a dielectric layer 64, redistribution wirings 66 and a dielectric layer 68 is formed on the de-bonding layer 62 such that the de-bonding layer 62 is between the carrier 60 and the dielectric layer 64 of the redistribution circuit structure 61. As shown in FIG. 4A, the dielectric layer 64 is formed on the de-bonding layer 62. In some embodiments, the dielectric layer 64 is formed of a polymer, which may also be a photo-sensitive material such as polybenzoxazole (PBO), polyimide, benzocyclobutene (BCB), or the like, which may be easily patterned using a photolithography process followed by an etch process. In some embodiments, the dielectric layer 64 is formed of a nitride such as silicon nitride, an oxide such as silicon oxide, PhosphoSilicate Glass (PSG), BoroSilicate Glass (BSG), Boron-doped PhosphoSilicate Glass (BPSG), or the like. As shown in FIG. 4B, the redistribution wirings 66 are formed over the dielectric layer 64. The formation of the redistribution wirings 66 may include forming a seed layer (not shown) over the dielectric layer 64, forming a patterned mask (not shown) such as a photoresist layer over the seed layer, and then performing a plating process on the exposed seed layer. The patterned mask and the portions of the seed layer covered by the patterned mask are then removed, leaving the redistribution wirings 66 as shown in FIG. 4B. In accordance with some embodiments, the seed layer includes a titanium layer and a copper layer over the titanium layer. The seed layer may be formed using, for example, Physical Vapor Deposition (PVD). The plating may be performed using, for example, electroless plating. As shown in FIG. 4C, the dielectric layer 68 is formed over the dielectric layer 64 to cover the redistribution wirings 66. The bottom surface of the dielectric layer 68 is in contact with the top surfaces of the redistribution wirings 66 and the dielectric layer 64. In accordance with some embodiments of the present disclosure, the dielectric layer 68 is formed of a polymer, which may be a photo-sensitive material such as PBO, polyimide, BCB, or the like. In some embodiments, the dielectric layer 68 is formed of a nitride such as silicon nitride, an oxide such as silicon oxide, PSG, BSG, BPSG, or the like. The dielectric layer 68 is then patterned to form openings 70 therein. Hence, portions of the redistribution wirings 66 are exposed through the openings 70 in the dielectric layer 68. FIG. 4C and the subsequent figures illustrate a single redistribution circuit structure 61 having a single layer of redistribution wirings 66 for illustrative purposes and some embodiments may have a plurality of layers of redistribution wirings 66 by repeating the process discussed above.

Referring to FIG. 4D, after forming the redistribution circuit structure 61 over the de-bonding layer 62 carried by the carrier 60, metal posts 72 are formed on the redistribution circuit structure 61 and electrically connected to the redistribution wirings 66 of the redistribution circuit structure 61. Throughout the description, the metal posts 72 are alternatively referred to as conductive through-vias 72 since the metal posts 72 penetrate through the subsequently formed molding material (shown in FIG. 4G). In some embodiments, the conductive through-vias 72 are formed by plating. The plating of the conductive through-vias 72 may include forming a blanket seed layer (not shown) over the dielectric layer 68 and extending into the openings 70 shown in FIG. 4C, forming and patterning a photoresist (not shown), and plating the conductive through-vias 72 on the portions of the seed layer that are exposed through the openings in the photoresist. The photoresist and the portions of the seed layer that were covered by the photoresist are then removed. The material of the conductive through-vias 72 may include copper, aluminum, or the like. The conductive through-vias 72 may have the shape of rods. The top-view shapes of the conductive through-vias 72 may be circles, rectangles, squares, hexagons, or the like.

Referring FIG. 4E, after forming the conductive through vias 72, at least one singulated SoIC structure, e.g., the singulated SoIC structure 50 shown in FIG. 2 or the singulated SoIC structure 50′ shown in FIG. 3, is picked and placed over the dielectric layer 68 of the redistribution circuit structure 61. Only a single singulated SoIC structure 50 or 50′ and conductive through-vias 72 are illustrated in FIG. 4E for illustrative purposes. It is noted, however, that the process steps shown in FIG. 4A through FIG. 4M may be performed at wafer level, and are performed on all of the singulated SoIC structure 50 or 50′ and the conductive through-vias 72 disposed over the carrier 60. As illustrated in FIG. 4E, the semiconductor die 11a is stacked over the semiconductor dies 20, and the support substrate 30 in the singulated SoIC structure 50 or 50′ may be adhered to the dielectric layer 68 through, for example, a die-attachment film (not shown).

Referring to FIG. 4F, an insulating encapsulation material 76 is formed over the redistribution circuit structure 61 to cover the SoIC structure 50 or 50′ and the conductive through-vias 72. The insulating encapsulation material 76 may be a molding compound (e.g., epoxy or other suitable resin) formed through an over-molding process. The insulating encapsulation material 76 fills the gaps between neighboring conductive through-vias 72 and the gaps between the conductive through-vias 72 and the SoIC structure 50 or 50′. The top surface of the insulating encapsulation material 76 is higher than the conductive through-vias 72. Furthermore, tapered sidewalls of the SoIC structure 50 or 50′ are laterally covered by the insulating encapsulation material 76.

Next, as shown in FIG. 4G, a planarization process, such as a Chemical Mechanical Polish (CMP) process and/or a mechanical grinding process, is performed to partially remove the insulating encapsulation material 76 until the conductive through-vias 72 and the conductive terminals 48 are revealed. After the insulating encapsulation material 76 is thinned down, an insulating encapsulant 76′ is formed to laterally encapsulate the SoIC structure 50 or 50′ and the conductive through vias 72. Due to the planarization, the top ends of conductive through-vias 72 are substantially level or coplanar with the revealed surfaces of the conductive terminals 48 and the top surface of the insulating encapsulant 76′, within process variations. In the illustrated exemplary embodiments, the planarization is performed until the conductive through-vias 72 and the conductive terminals 48 are revealed. Furthermore, the insulating encapsulant 76′ may fill the gaps between the conductive terminals 48.

FIG. 4H through FIG. 4M illustrate formation of a redistribution circuit structure 77 and solder regions. As shown in FIG. 4H through FIG. 4L, a redistribution circuit structure 77 including a dielectric layer 78, redistribution wirings 80, a dielectric layer 82, redistribution wirings 86, and a dielectric layer 88 is formed on the substrates 12 and the insulating encapsulant 76′. As shown in FIG. 4M, solder regions including Under-Bump Metallurgies (UBMs) 92 and electrical connectors 94 disposed on the UBMs 92 are formed on the redistribution circuit structure 77.

Referring to FIG. 4H, a dielectric layer 78 is formed on the top tier semiconductor dies 20 of the SoIC structure 50 or 50′ and the insulating encapsulant 76′. In some embodiments, the dielectric layer 78 is formed of a polymer such as PBO, polyimide, or the like. In some embodiments, dielectric layer 78 is formed of silicon nitride, silicon oxide, or the like. The openings 79 are formed in the dielectric layer 78 to expose the conductive terminals 48 and the conductive through-vias 72. The formation of the openings 79 may be performed through a photolithography process followed by an etch process.

Next, referring to FIG. 4I, redistribution wirings 80 are formed to connect to the conductive terminals 48 and the conductive through-vias 72. The redistribution wirings 80 may include metal traces (metal lines) over the dielectric layer 78 as well as metal vias extending into the openings 79 (shown in FIG. 4H) to electrically connect to the conductive through-vias 72 and the conductive terminals 48. In some embodiments, the redistribution wirings 80 are formed in a plating process, wherein each of the redistribution wirings 80 includes a seed layer (not shown) and a plated metallic material over the seed layer. The seed layer and the plated material may be formed of the same material or different materials. The redistribution wirings 80 may comprise a metal or a metal alloy including aluminum, copper, tungsten, and alloys thereof. The redistribution wirings 80 are formed of non-solder materials. The via portions of the redistribution wirings 80 may be in physical contact with the top surfaces of the conductive terminals 48.

Referring to FIG. 4J, a dielectric layer 82 is formed over the redistribution wirings 80 and the dielectric layer 78. The dielectric layer 82 may be formed using a polymer, which may be selected from the same candidate materials as those of the dielectric layer 78. For example, the dielectric layer 82 may include PBO, polyimide, BCB, or the like. In some embodiments, the dielectric layer 82 may include non-organic dielectric materials such as silicon oxide, silicon nitride, silicon carbide, silicon oxynitride, or the like. The openings 84 are also formed in the dielectric layer 82 to expose the redistribution wirings 80. The formation of the openings 84 may be performed through a photolithography process followed by an etch process.

Referring to FIG. 4K, FIG. 4K illustrates the formation of redistribution wirings 86, which are electrically connected to the redistribution wirings 80. The formation of the redistribution wirings 86 may adopt similar methods and materials to those for forming the redistribution wirings 80.

Referring to FIG. 4L, an additional dielectric layer 88, which may be a polymer layer, is formed to cover the redistribution wirings 86 and the dielectric layer 82. The dielectric layer 88 may be selected from the same candidate polymers used for forming the dielectric layers 78 and 82. Openings 90 are then formed in the dielectric layer 88 to expose the metal pad portions of redistribution wirings 86. The formation of the openings 90 may be performed through a photolithography process followed by an etch process.

FIG. 4M illustrates the formation of the UBMs 92 and the electrical connectors 94 in accordance with some exemplary embodiments. Referring to FIG. 4M, the formation of the UBMs 92 may include deposition and patterning. The formation of the electrical connectors 94 may include placing solder on the exposed portions of the UBMs 92 and then reflowing the solder to form solder balls. In some embodiments, the formation of the electrical connectors 94 includes performing a plating step to form solder regions over redistribution wirings 86 and then reflowing the solder regions. The electrical connectors 94 may also include metal pillars or metal pillars and solder caps, which may also be formed through plating. Throughout the description, the combined structure including the SoIC structure 50 or 50′, the conductive through-vias 72, the insulating encapsulant 76′, the redistribution circuit structures 61 and the redistribution circuit structures 77 is referred to as a package 100, which may be a composite wafer with a round top-view shape.

Next, the package 100 is de-bonded from carrier 60. The de-bonding layer 62 is also cleaned from the package 100. The de-bonding may be performed by irradiating a light such as UV light or laser on the de-bonding layer 62 to decompose the de-bonding layer 62. In the de-bonding process, a tape (not shown) may be adhered onto the dielectric layer 88 and the electrical connectors 94. In subsequent steps, the carrier 60 and the de-bonding layer 62 are removed from the package 100. A die saw process is performed to saw the package 100 into multiple Integrated Fan-out (InFO) package packages, each including at least one SoIC structure 50 or 50′, conductive through-vias 72, an insulating encapsulant 76′, a redistribution circuit structures 61, and a redistribution circuit structures 77.

In some embodiments, another package (not shown) may be stacked over and bonded with the package 100 such that a package on package (PoP) structure is formed. The package stacked over the package 100 may be a package including memory dies, such as Static Random Access Memory (SRAM) dies, Dynamic Random Access Memory (DRAM) dies, or the like.

In accordance with some embodiments of the disclosure, a SoIC structure including a first semiconductor die, a second semiconductor die and a dielectric material is provided. The first semiconductor die includes a first portion and a second portion surrounding the first portion, the second potion includes a curved surface, and the first portion of the first semiconductor die includes first tapered sidewalls. The second semiconductor die is disposed over the first portion and electrically connected to the first semiconductor die. The dielectric material is disposed over the first semiconductor die and laterally encapsulates the second semiconductor die, wherein the dielectric material includes second tapered sidewalls, the curved surface of the second portion is uncovered by the dielectric material and the second semiconductor die, and a first maximum width of the first semiconductor die is greater than a second maximum width of the dielectric material. In some embodiments, a first minimum width of the first semiconductor die is greater than a second minimum width of the dielectric material. In some embodiments, the curved surface is connected between the first tapered sidewalls of the first semiconductor die and the second tapered sidewalls of the dielectric material. In some embodiments, the SoIC structure further includes a recast layer covering the first tapered sidewalls, wherein the recast layer does not cover the second tapered sidewalls. In some embodiments, the first semiconductor die includes a first substrate, a first interconnect structure disposed on a front surface of the first substrate, and a first bonding structure disposed on and electrically connected to the first interconnect structure, wherein the curved surface is distributed in the first bonding structure, the first bonding structure is in contact with the second semiconductor die and the dielectric material, and the first bonding structure has the first maximum width of the first semiconductor die. In some embodiments, the first semiconductor die further includes a backside redistribution structure disposed on a back surface of the first substrate, wherein the backside redistribution structure has the first minimum width of the first semiconductor die. In some embodiments, the first substrate has a first surface interfacing the first interconnect structure, and a first included angle between the first surface of the first substrate and the sidewalls of the first semiconductor die is less than 90 degrees. In some embodiments, the dielectric material has a second surface interfacing the first bonding structure, and a second included angel between the second surface of the dielectric material and the sidewalls of the dielectric material is less than 90 degrees. In some embodiments, the second semiconductor die includes a second substrate, a second interconnect structure disposed on a front surface of the second substrate, and a second bonding structure disposed on and electrically connected to the second interconnect structure, wherein the second bonding structure is in contact with and electrically connected to the first bonding structure. In some embodiments, the SoIC structure further includes a support substrate, wherein the second semiconductor die and the dielectric material are disposed between the first semiconductor die and the support substrate.

In accordance with some other embodiments of the disclosure, a fabricating method of a SoIC structure including following steps is provided. A semiconductor wafer including first semiconductor dies is provided. Second semiconductor dies are provided and bonded with the semiconductor wafer. A dielectric material is formed on the semiconductor wafer to laterally encapsulate the second semiconductor dies. A sawing process is performed to cut the dielectric material to reveal the semiconductor wafer. After performing the sawing process, a laser grooving process is performed to singulate the semiconductor wafer to obtain singulated structures, wherein the first semiconductor die in one of the singulated structures comprises a first portion and a second portion surrounding the first portion, the second potion comprises a curved surface, and the first portion of the first semiconductor die comprises first tapered sidewalls, and wherein the dielectric material comprises second tapered sidewall and curved surfaces are formed on the semiconductor wafer after performing the sawing process. In some embodiments, a first minimum width of the first semiconductor die in one of the singulated structures is greater than a second minimum width of the dielectric material in one of the singulated structures, and a difference between the first minimum width and the second minimum width is greater than about 2 micrometers. In some embodiments, a first maximum width of the first semiconductor die in one of the singulated structures is greater than a second maximum width of the dielectric material in one of the singulated structures, and a difference between the first maximum width and the second maximum width is greater than about 8 micrometers. In some embodiments, a cutting width of the sawing process is greater than a cutting width of the laser grooving process. In some embodiments, a recast layer is formed to cover the first tapered sidewalls of the first semiconductor die in one of the singulated structures after performing the sawing process. In some embodiments, the recast layer is formed to be spaced from the dielectric material.

In accordance with some other embodiments of the disclosure, a fabricating method of a SoIC structure including following steps is provided. Semiconductor dies are provided and bonded with a semiconductor wafer. A dielectric material is formed on the semiconductor wafer to laterally encapsulate the semiconductor dies. A singulation process including a wafer sawing process followed by a laser grooving process is performed. In some embodiments, the wafer sawing process is performed to cut the dielectric material along first scribe lines. In some embodiments, the laser grooving process is performed to cut the semiconductor wafer along second scribe lines. In some embodiments, a cutting width of the wafer sawing process is greater than a cutting width of the laser grooving process.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a first semiconductor die comprising a first portion and a second portion surrounding the first portion, the second potion comprising a curved surface, and the first portion of the first semiconductor die comprising first tapered sidewalls;
a second semiconductor die disposed over the first portion of the first semiconductor die and electrically connected to the first semiconductor die; and
a dielectric material disposed over the first semiconductor die and laterally encapsulating the second semiconductor die, wherein the dielectric material comprises second tapered sidewalls, the curved surface of the second portion is uncovered by the dielectric material and the second semiconductor die, and a first maximum width of the first semiconductor die is greater than a second maximum width of the dielectric material.

2. The structure of claim 1, wherein a first minimum width of the first semiconductor die is greater than a second minimum width of the dielectric material.

3. The structure of claim 1, wherein the curved surface is connected between the first tapered sidewalls of the first semiconductor die and the second tapered sidewalls of the dielectric material.

4. The structure of claim 1 further comprising:
a recast layer covering the first tapered sidewalls, wherein the recast layer does not cover the second tapered sidewalls.

5. The structure of claim 2, wherein the first semiconductor die comprises:
a first substrate;
a first interconnect structure disposed on a front surface of the first substrate; and
a first bonding structure disposed on and electrically connected to the first interconnect structure, wherein the curved surface is distributed in the first bonding structure, the first bonding structure is in contact with the second semiconductor die and the dielectric material, and the first bonding structure has the first maximum width of the first semiconductor die.

6. The structure of claim 5, wherein the first semiconductor die further comprises:
a backside redistribution structure disposed on a back surface of the first substrate, wherein the backside redistribution structure has the first minimum width of the first semiconductor die.

7. The structure of claim 5, wherein the first substrate has a first surface interfacing the first interconnect structure, and a first included angle between the first surface of the first substrate and the sidewalls of the first semiconductor die is less than 90 degrees.

8. The structure of claim 5, wherein the dielectric material has a second surface interfacing the first bonding structure, and a second included angel between the second surface of the dielectric material and the sidewalls of the dielectric material is less than 90 degrees.

9. The structure of claim 5, wherein the second semiconductor die comprises:
a second substrate;
a second interconnect structure disposed on a front surface of the second substrate; and
a second bonding structure disposed on and electrically connected to the second interconnect structure, wherein the second bonding structure is in contact with and electrically connected to the first bonding structure.

10. The structure of claim 1 further comprising:
a support substrate, wherein the second semiconductor die and the dielectric material are disposed between the first semiconductor die and the support substrate.

11. A method, comprising:
providing a semiconductor wafer comprising first semiconductor dies;
bonding second semiconductor dies with the semiconductor wafer;
forming a dielectric material on the semiconductor wafer to laterally encapsulate the second semiconductor dies;
performing a sawing process to cut the dielectric material to reveal the semiconductor wafer; and
after performing the sawing process, performing a laser grooving process to singulate the semiconductor wafer to obtain singulated structures,
wherein the first semiconductor die in one of the singulated structures comprises a first portion and a second portion surrounding the first portion, the second potion comprises a curved surface, and the first portion of the first semiconductor die comprises first tapered sidewalls,
wherein the dielectric material comprises second tapered sidewall and curved surfaces are formed on the semiconductor wafer after performing the sawing process.

12. The structure of claim 11, wherein a first minimum width of the first semiconductor die in one of the singulated structures is greater than a second minimum width of the dielectric material in one of the singulated structures, and a difference between the first minimum width and the second minimum width is greater than about 2 micrometers.

13. The structure of claim 12, wherein a first maximum width of the first semiconductor die in one of the singulated structures is greater than a second maximum width of the dielectric material in one of the singulated structures, and a difference between the first maximum width and the second maximum width is greater than about 8 micrometers.

14. The structure of claim 11, wherein a cutting width of the sawing process is greater than a cutting width of the laser grooving process.

15. The structure of claim 11, wherein a recast layer is formed to cover the first tapered sidewalls of the first semiconductor die in one of the singulated structures after performing the sawing process.

16. The structure of claim 15, wherein the recast layer is formed to be spaced from the dielectric material.

17. A method, comprising:
bonding semiconductor dies with a semiconductor wafer;
forming a dielectric material on the semiconductor wafer to laterally encapsulate the semiconductor dies; and
performing a singulation process comprising a wafer sawing process followed by a laser grooving process.

18. The method of claim 17, wherein the wafer sawing process is performed to cut the dielectric material along first scribe lines.

19. The method of claim 18, wherein the laser grooving process is performed to cut the semiconductor wafer along second scribe lines.

20. The method of claim 17, wherein a cutting width of the wafer sawing process is greater than a cutting width of the laser grooving process.
